(19) United States
(12) Patent Application Publication
(10) Pub. No.: US 2021/0126620 A1
(43) Pub. Date: Apr. 29, 2021

(54) RADIO FREQUENCY FILTERING CIRCUITRY

(71) Applicant: Qorvo US, Inc., Greensboro, NC (US)

(72) Inventor: Peter V. Wright, Portland, OR (US)

(21) Appl. No.: 17/079,286

(22) Filed: Oct. 23, 2020

Related U.S. Application Data
(60) Provisional application No. 62/925,489, filed on Oct. 24, 2019.

(51) Int. Cl. H03H 9/54; H03H 9/15

(52) U.S. Cl. CPC H03H 9/542; H03H 9/15

(57) ABSTRACT

Radio frequency (RF) filtering circuitry includes an input node, an output node, a shunt node, a first bulk acoustic wave (BAW) resonator, a second BAW resonator, a first inductor, and a second inductor. The first BAW resonator is coupled between the input node and the output node. The second BAW resonator is coupled between an intermediate node and the shunt node. The first inductor is coupled between the input node and the intermediate node. The second inductor is coupled between the output node and the intermediate node.

### FIELD OF THE DISCLOSURE

The present disclosure is related to radio frequency (RF) filtering circuitry, and in particular to RF filtering circuitry providing a notch filter response.

### BACKGROUND

Filtering circuitry for radio frequency (RF) signals is a crucial component of modern communications devices. As wireless communications standards continue to evolve, the requirements placed on filtering circuitry for RF signals continue to increase in stringency. For example, filtering circuitry for communications devices conforming to fifth generation (5G) wireless communications standards are required to have high bandwidth, high selectivity, and low insertion loss. Conventional filtering circuitry generally offers a relatively poor tradeoff between these performance characteristics. Accordingly, there is a need for improved filtering circuitry for RF signals.

### SUMMARY

In one embodiment, radio frequency (RF) filtering circuitry includes an input node, an output node, a shunt node, a first bulk acoustic wave (BAW) resonator, a second BAW resonator, a first inductor, and a second inductor. The first BAW resonator is coupled between the input node and the output node. The second BAW resonator is coupled between an intermediate node and the shunt node. The first inductor is coupled between the input node and the intermediate node. The second inductor is coupled between the output node and the intermediate node. Using BAW resonators in the RF filtering circuitry provides significant improvements in the filter response of the RF filtering circuitry when compared to conventional designs.

In one embodiment, a series resonance frequency of the first BAW resonator is less than a series resonance frequency of the second BAW resonator. Further, a coupling factor between the first inductor and the second inductor may be greater than or equal to zero. Providing the RF filtering circuitry in this way provides significant improvements in the filter response of the RF filtering circuitry when compared to conventional designs.

In one embodiment, a series resonance frequency of the first BAW resonator is greater than a series resonance frequency of the second BAW resonator. Further, a coupling factor between the first inductor and the second inductor may be less than or equal to zero. Providing the RF filtering circuitry in this way provides significant improvements in the filter response of the RF filtering circuitry when compared to conventional designs.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a functional schematic illustrating radio frequency (RF) filtering circuitry according to one embodiment of the present disclosure.

FIG. 2 is a graph illustrating a filter response of RF filtering circuitry according to one embodiment of the present disclosure.

FIGS. 3A through 3E are functional schematics illustrating equivalent circuitry for RF filtering circuitry according to one embodiment of the present disclosure.

FIGS. 4A and 4B are graphs illustrating a filter response of RF filtering circuitry according to one embodiment of the present disclosure.

FIG. 5 is a graph illustrating a filter response of RF filtering circuitry according to one embodiment of the present disclosure.

FIGS. 6A through 6E are functional schematics illustrating equivalent circuitry for RF filtering circuitry according to one embodiment of the present disclosure.

FIG. 7 is a graph illustrating a filter response of RF filtering circuitry according to one embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

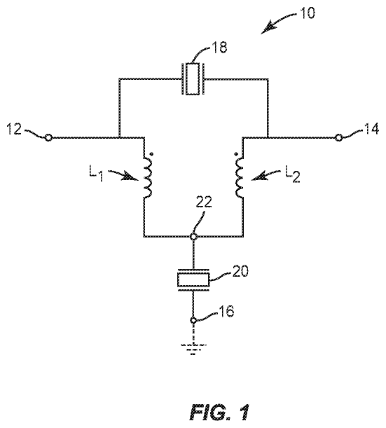

FIG. 1 shows radio frequency (RF) filtering circuitry 10 according to one embodiment of the present disclosure. The RF filtering circuitry 10 includes an input node 12, an output node 14, a shunt node 16, a first bulk acoustic wave (BAW) resonator 18 coupled between the input node 12 and the output node 14, a second BAW resonator 20 coupled between an intermediate node 22 and the shunt node 16, a first inductor L₁ coupled between the input node 12 and the intermediate node 22, and a second inductor L₂ coupled between the output node 14 and the intermediate node 22. The first inductor L₁ and the second inductor L₂ may be coupled (i.e., magnetically) with some coupling factor k as represented by the coupling dots in FIG. 1.

In operation, RF signals are provided at the input node 12. The RF filtering circuitry 10 provides a notch filter response such that RF signals falling within an undesired frequency band are shunted from the input node 12 to the shunt node 16, while RF signals outside of the undesired frequency band are passed from the input node 12 to the output node 14. In some embodiments, the shunt node 16 is coupled to ground such that the RF signals within the undesired frequency band are shunted to ground. In other embodiments, the shunt node 16 may be connected to other circuitry.

The resonance frequency of the first BAW resonator 18 and the second BAW resonator 20 as well as the coupling factor k between the first inductor L₁ and the second inductor L₂ may be adjusted to change a filter response of the RF filtering circuitry 10. In some embodiments, a resonance frequency of the first BAW resonator 18 is different from a resonance frequency of the second BAW resonator 20. In particular, in a first embodiment a series resonance frequency of the first BAW resonator 18 may be below a series resonance frequency of the second BAW resonator 20. In such an embodiment, a coupling factor k between the first inductor L₁ and the second inductor L₂ may be greater than or equal to zero. In a second embodiment the series resonance frequency of the first BAW resonator 18 may be above the series resonance frequency of the second BAW resonator 20. In such an embodiment, the coupling factor k between the first inductor L₁ and the second inductor L₂ may be less than or equal to zero. In various embodiments, an inductance of the first inductor L₁ and the second inductor L₂ may be equal. However, the inductance of the first inductor L₁ and the second inductor L₂ may be different, for example, if an impedance at the input node 12 and the output node 14 are unequal.

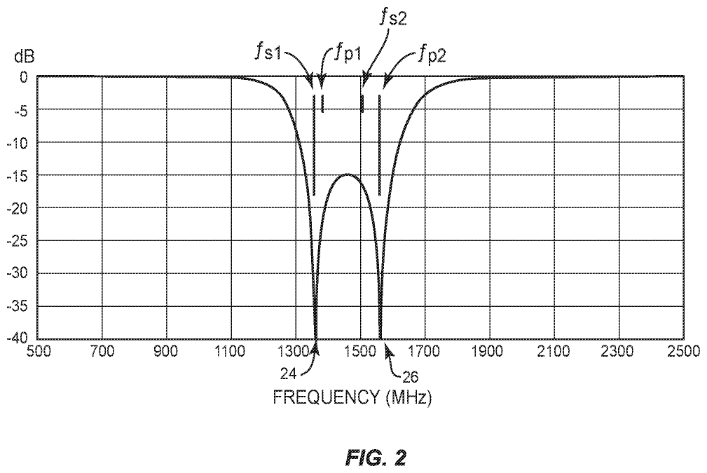

FIG. 2 is a graph illustrating a filter response of the RF filtering circuitry 10 when the series resonance frequency of the first BAW resonator 18 is less than the series resonance frequency of the second BAW resonator 20 and the coupling factor k between the first inductor L₁ and the second inductor L₂ is greater than or equal to zero. Specifically, FIG. 2 shows the filter response of the RF filtering circuitry 10 when the coupling factor k between the first inductor L₁ and the second inductor L₂ is equal to zero. As shown, the RF filtering circuitry 10 provides a notch response having a first valley 24 and a second valley 26. The first valley 24 occurs at the series resonance frequency of the first BAW resonator 18, while the second valley 26 occurs at a parallel resonance frequency of the second BAW resonator 20. For reference, the series resonance frequency of the first BAW resonator 18 is indicated in the graph as fₛ₁, a parallel resonance frequency of the first BAW resonator 18 is indicated in the graph as fₚ₁, the series resonance frequency of the second BAW resonator 20 is indicated in the graph as fₛ₂, and the parallel resonance frequency of the second BAW resonator 20 is indicated in the graph as fₚ₂.

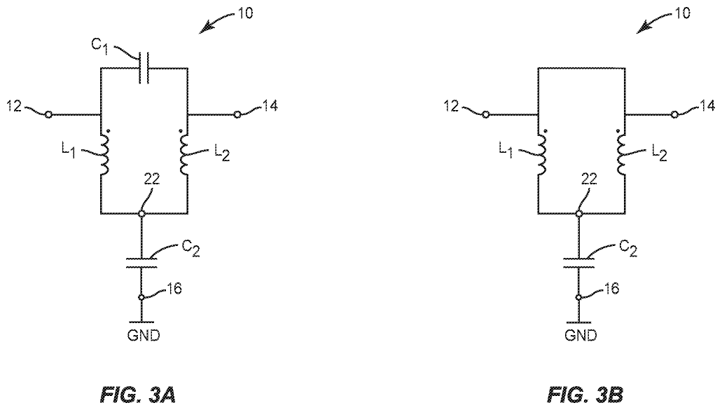

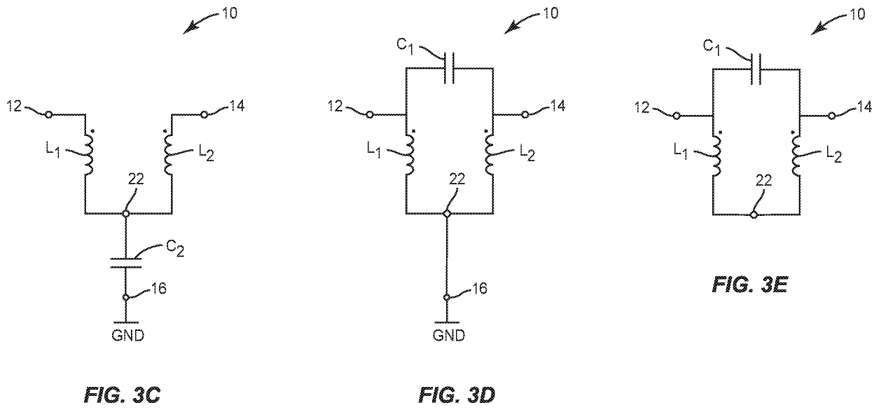

At frequencies lower than the series resonance frequency of the first BAW resonator 18 and higher than the parallel resonance frequency of the second BAW resonator 20, the first BAW resonator 18 and the second BAW resonator 20 appear as capacitive elements in the RF filtering circuitry 10. An equivalent circuit for the RF filtering circuitry 10 at these frequencies is shown in FIG. 3A. As shown, the first BAW resonator 18 is replaced with a first BAW resonator capacitance C₁ and the second BAW resonator 20 is replaced with a second BAW resonator capacitance C₂. The first BAW resonator capacitance C₁ and the second BAW resonator capacitance C₂ represent the static capacitance of the first BAW resonator 18 and the second BAW resonator 20, respectively. Those skilled in the art will appreciate that the equivalent circuit shown in FIG. 3A can be designed to be an all-pass network in which all frequencies are passed with equal gain. A static capacitance of the first BAW resonator 18 and the second BAW resonator 20 may be designed along with an inductance of the first inductor L₁ and the second inductor L₂ such that the RF filtering circuitry 10 acts as an all-pass network below the series resonance frequency of the first BAW resonator 18 and above the parallel resonance frequency of the second BAW resonator 20.

At the series resonance frequency of the first BAW resonator 18, an impedance of the first BAW resonator 18 is at a low point, such that the first BAW resonator 18 essentially acts as a short circuit. The second BAW resonator 20 still appears as a capacitive element. An equivalent circuit for the RF filtering circuitry 10 at the series resonant frequency of the first BAW resonator 18 is shown in FIG. 3B. As shown, the first BAW resonator 18 is replaced with a short circuit and the second BAW resonator 20 is replaced with a second BAW resonator capacitance C₂. Those skilled in the art will appreciate that the equivalent circuit shown in FIG. 3B is an LC series resonant circuit. A resonance frequency of the first inductor L₁, the second inductor L₂, and the second BAW resonator capacitance C₂ can be designed to be equal to the series resonance frequency of the first BAW resonator 18. At the resonance frequency of the first inductor L₁, the second inductor L₂, and the second BAW resonator capacitor C₂, the combination of these elements appears as a short circuit between the input node 12 and the shunt node 16. This causes the first valley 24 shown in FIG. 2.

At the parallel resonance frequency of the first BAW resonator 18, an impedance of the first BAW resonator 18 is at a high point, such that the first BAW resonator 18 essentially acts as an open circuit. The second BAW resonator 20 still appears as a capacitive element. An equivalent circuit for the RF filtering circuitry 10 at the parallel resonant frequency of the first BAW resonator 18 is shown in FIG. 3C. As shown, the first BAW resonator 18 is replaced with an open circuit and the second BAW resonator 20 is replaced with a second BAW resonator capacitance C₂. The second BAW resonator capacitance C₂ can be designed along with an inductance of the first inductor L₁ and the second inductor L₂ to partially shunt signals between the input node 12 and the shunt node 16 in this configuration. This causes the filter response seen between the series resonance frequency of the first BAW resonator 18 and the parallel resonance frequency of the first BAW resonator 18.

At the series resonance frequency of the second BAW resonator 20, an impedance of the second BAW resonator 20 is at a low point, such that the second BAW resonator 20 essentially acts as a short circuit. The first BAW resonator 20 still appears as a capacitive element. An equivalent circuit for the RF filtering circuitry 10 at the series resonance frequency of the second BAW resonator 20 is shown in FIG. 3D. As shown, the first BAW resonator 18 is replaced with a first BAW resonator capacitance C₁ and the second BAW resonator 20 is replaced with a short circuit. The first BAW resonator capacitance C₁ can be designed along with an inductance of the first inductor L₁ and the second inductor L₂ to partially shunt signals between the input node 12 and the shunt node 16 in this configuration. This causes the filter response seen between the parallel resonance frequency of the first BAW resonator 18 and the series resonance frequency of the second BAW resonator 20.

At the parallel resonance frequency of the second BAW resonator 20, an impedance of the second BAW resonator 20 is at a high point, such that the second BAW resonator 20 acts as an open circuit. The first BAW resonator 18 still appears as a capacitive element. An equivalent circuit for the RF filtering circuitry 10 at the parallel resonance frequency of the second BAW resonator 20, fₚ₂, is shown in FIG. 3E. As shown, the first BAW resonator 18 is replaced with a first BAW resonator capacitance C₁ and the second BAW resonator 20 is replaced with an open circuit. Those skilled in the art will appreciate that the equivalent circuit shown in FIG. 3E is an LC parallel resonant circuit (i.e., a tank circuit). A resonance frequency of the first inductor L₁, the second inductor L₂, and the first BAW resonator capacitance C₁ can be designed to be equal to the parallel resonance frequency of the second BAW resonator 20. At the resonance frequency of the first inductor L₁, the second inductor L₂, and the first BAW resonator capacitance C₁, the combination of these elements appears as an open circuit between the input node 12 and the output node 14. This causes the second valley 26 shown in FIG. 2.

The combined inductance of the first inductor L₁ and the second inductor L₂ may need to be different to achieve the desired resonance responses between the inductors, the first BAW resonator capacitance C₁, and the second BAW resonator capacitance C₂ for each one of the equivalent circuits discussed above. Introducing coupling (i.e., magnetic coupling) between the first inductor L₁ and the second inductor L₂ may make this possible. By introducing positive coupling (i.e., a positive coupling factor k) between the first inductor L₁ and the second inductor L₂, the combined inductance of the first inductor L₁ and the second inductor L₂ may be greater in the equivalent circuit shown in FIG. 3B than in the equivalent circuit shown in FIG. 3E. This is because in the equivalent circuit shown in FIG. 3B the first inductor L₁ and the second inductor L₂ are coupled in parallel in the signal path, while in the equivalent circuit shown in FIG. 3E the first inductor L₁ and the second inductor L₂ are coupled in series in the signal path. This affects how the inductance of the first inductor L₁ and the second inductor L₂ are summed and in turn how the coupling between them affects the sum of their inductance. Accordingly, coupling the first inductor L₁ and the second inductor L₂ in this way may allow for better tuning of the resonant responses of the equivalent circuits discussed above.

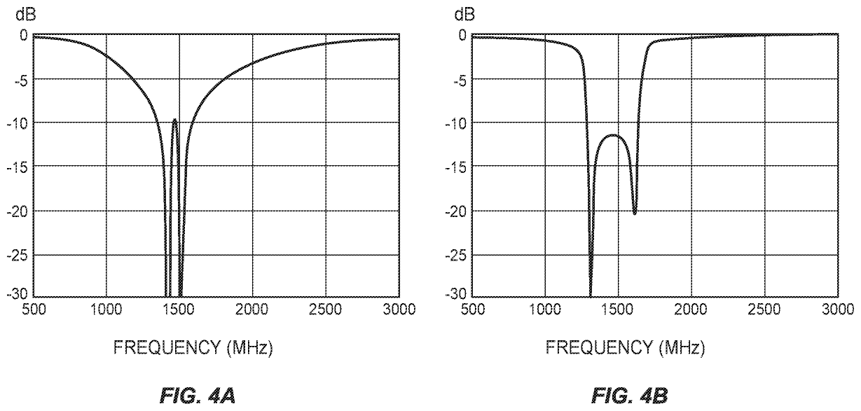

FIGS. 4A and 4B illustrate the effect of the coupling factor k between the first inductor L₁ and the second inductor L₂ on the filter response of the RF filtering circuitry 10. In FIG. 4A, the coupling factor k between the first inductor L₁ and the second inductor L₂ is zero. In FIG. 4B, the coupling factor k between the first inductor L₁ and the second inductor L₂ is 0.7. As shown, changing the coupling factor k between the first inductor L₁ and the second inductor L₂ affects the roll-off of the notch filter response, the width of the notch filter response, the center frequency of the notch filter response, and the attenuation provided by the notch filter response. The coupling factor k between the first inductor L₁ and the second inductor L₂ can be adjusted to produce a desired filter response.

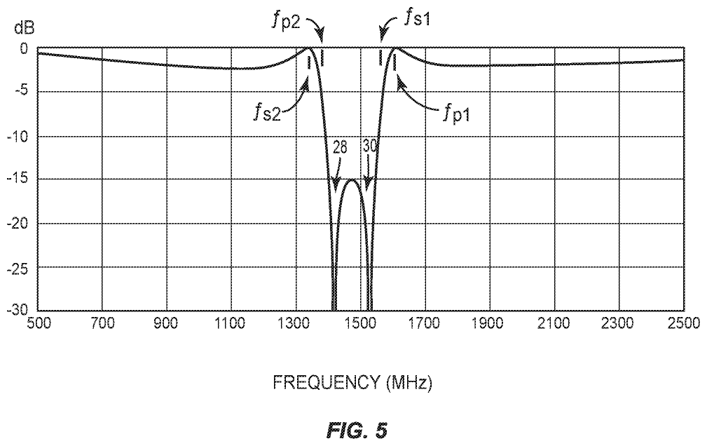

FIG. 5 is a graph illustrating a filter response of the RF filtering circuitry 10 when the series resonance frequency of the first BAW resonator 18 is greater than the series resonance frequency of the second BAW resonator 20 and the coupling factor k between the first inductor L₁ and the second inductor L₂ is less than or equal to zero. Specifically, the graph in FIG. 5 shows the filter response of the RF filtering circuitry 10 when the coupling factor k between the first inductor L₁ and the second inductor L₂ is equal to zero. Similar to the graph shown in FIG. 2, the RF filtering circuitry 10 provides a notch response having a first valley 28 and a second valley 30. The first valley 28 occurs at the parallel resonance frequency of the second BAW resonator 20, while the second valley 30 occurs at the series resonance frequency of the first BAW resonator 18. For reference, the series resonance frequency of the first BAW resonator 18 is indicated in the graph as fₛ₁, the parallel resonance frequency of the first BAW resonator 18 is indicated in the graph as fₚ₁, the series resonance frequency of the second BAW resonator 20 is indicated in the graph as fₛ₂, and the parallel resonance frequency of the second BAW resonator 20 is indicated in the graph as fₚ₂. As shown, the RF filtering circuitry 10 provides more insertion loss outside of the notch response in this configuration when compared with the one above described with respect to FIG. 2.

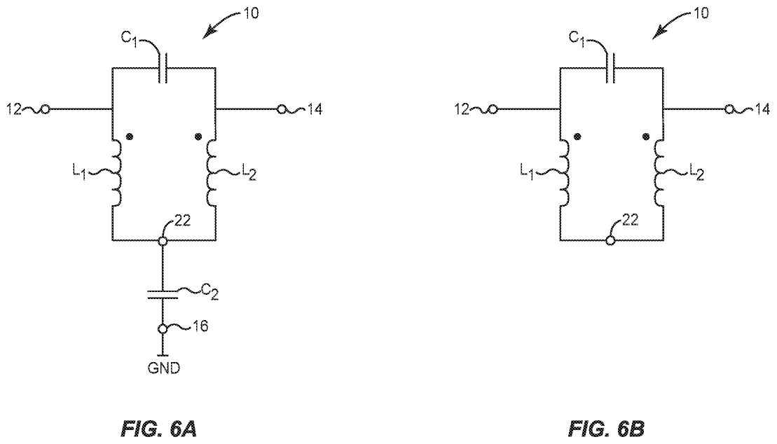

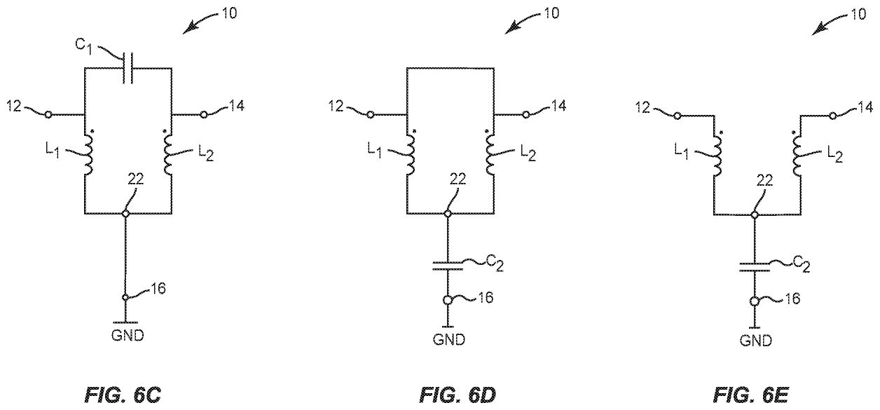

At frequencies lower than the parallel resonance frequency of the second BAW resonator 20 and higher than the series resonance frequency of the first BAW resonator 18, the first BAW resonator 18 and the second BAW resonator 20 appear as capacitive elements in the RF filtering circuitry 10. An equivalent circuit for the RF filtering circuitry 10 at these frequencies is shown in FIG. 6A. As shown, the first BAW resonator 18 is replaced with a first BAW resonator capacitance C₁ and the second BAW resonator 20 is replaced with a second BAW resonator capacitance C₂. The first BAW resonator capacitance C₁ and the second BAW resonator capacitance C₂ represent the static capacitance of the first BAW resonator 18 and the second BAW resonator 20, respectively. Those skilled in the art will appreciate that the equivalent circuit shown in FIG. 6A can be designed to be an all-pass network in which all frequencies are passed with equal gain. A static capacitance of the first BAW resonator 18 and the second BAW resonator 20 may be designed along with an inductance of the first inductor L₁ and the second inductor L₂ such that the RF filtering circuitry 10 acts as an all-pass network below the parallel resonance frequency of the second BAW resonator 20 and above the series resonance frequency of the first BAW resonator 18.

At the series resonance frequency of the second BAW resonator 20, an impedance of the second BAW resonator 20 is at a low point, such that the second BAW resonator 20 essentially acts as a short circuit. The first BAW resonator 18 still appears as a capacitive element. An equivalent circuit for the RF filtering circuitry 10 at the series resonant frequency of the second BAW resonator 20 is shown in FIG. 6B. As shown, the first BAW resonator 18 is replaced with a first BAW resonator capacitance C₁ and the second BAW resonator is replaced with a short circuit. Those skilled in the art will appreciate that the equivalent circuit shown in FIG. 6B can be designed to be an all-pass network as discussed above. That is, a static capacitance of the first BAW resonator 18 may be designed along with an inductance of the first inductor L₁ and the second inductor L₂ such that the RF filtering circuitry 10 acts as an all-pass network at the series resonance frequency of the second BAW resonator 20. This allows a very sharp corner of the filter response of the RF filtering circuitry 10 to be achieved at this frequency.

At the parallel resonance frequency of the second BAW resonator 20, an impedance of the second BAW resonator 20 is at a high point, such that the second BAW resonator 20 essentially acts as an open circuit. The first BAW resonator 18 still appears as a capacitive element. An equivalent circuit for the RF filtering circuitry 10 at the parallel resonant frequency of the second BAW resonator 20 is shown in FIG. 6C. As shown, the first BAW resonator 18 is replaced with a first BAW resonator capacitance C₁ and the second BAW resonator 20 is replaced with an open circuit. Those skilled in the art will appreciate that the equivalent circuit shown in FIG. 6C is an LC parallel resonant circuit (i.e., a tank circuit). A resonance frequency of the first inductor L₁, the second inductor L₂, and the first BAW resonator capacitance C₁ can be designed to equal the parallel resonance frequency of the second BAW resonator 20. At the resonance frequency of the first inductor L₁, the second inductor L₂, and the first BAW resonator capacitance C₁, the combination of these elements appears as an open circuit between the input node 12 and the output node 14. This causes the first valley 28 shown in FIG. 5.

At the series resonant frequency of the first BAW resonator 18, an impedance of the first BAW resonator 18 is at a low point, such that the first BAW resonator 18 essentially acts as a short circuit. The second BAW resonator 20 still appears as a capacitive element. An equivalent circuit for the RF filtering circuitry 10 at the series resonant frequency of the first BAW resonator 18 is shown in FIG. 6D. As shown, the first BAW resonator 18 is replaced with a short circuit and the second BAW resonator 20 is replaced with a second BAW resonator capacitance C₂. Those skilled in the art will appreciate that the equivalent circuit shown in FIG. 6D is an LC series circuit. A resonance frequency of the first inductor L₁, the second inductor L₂, and the second BAW resonator capacitance C₂ can be designed to equal the series resonant frequency of the first BAW resonator 18. At the resonance frequency of the first inductor L₁, the second inductor L₂, and the second BAW resonator capacitance C₂, the combination of these elements appears as a short circuit between the input node 12 and the shunt node 16. This causes the second valley 30 shown in FIG. 5.

At the parallel resonance frequency of the first BAW resonator 18, an impedance of the first BAW resonator 18 is at a high point, such that the first BAW resonator 18 essentially acts as an open circuit. The second BAW resonator 20 still appears as a capacitive element. An equivalent circuit for the RF filtering circuitry 10 at the parallel resonance frequency of the first BAW resonator 18 is shown in FIG. 6E. As shown, the first BAW resonator 18 is replaced with an open circuit and the second BAW resonator 20 is replaced with a second BAW resonator capacitance C₂. Those skilled in the art will appreciate that the equivalent circuit shown in FIG. 6E can be designed to be an all-pass network as discussed above. That is, a static capacitance of the second BAW resonator 20 may be designed along with an inductance of the first inductor L₁ and the second inductor L₂ such that the RF filtering circuitry 10 acts as an all-pass network at the parallel resonance frequency of the first BAW resonator 18. This allows a very sharp corner of the filter response of the RF filtering circuitry 10 to be achieved at this frequency.

As discussed above, the combined inductance of the first inductor L₁ and the second inductor L₂ may need to be different to achieve the desired resonance responses between the inductors, the first BAW resonator capacitance C₁, and the second BAW resonator capacitance C₂ for each one of the equivalent circuits discussed above. Introducing coupling (i.e., magnetic coupling) between the first inductor L₁ and the second inductor L₂ may make this possible. By introducing negative coupling (i.e., a negative coupling factor k) between the first inductor L₁ and the second inductor L₂, the combined inductance of the first inductor L₁ and the second inductor L₂ may be less in the equivalent circuit shown in FIG. 6B than in the equivalent circuit shown in FIG. 6D. This is because in the equivalent circuit shown in FIG. 6B the first inductor L₁ and the second inductor L₂ are coupled in series between the input node 12 and the shunt node 16, while in the equivalent circuit shown in FIG. 6D the first inductor L₁ and the second inductor L₂ are coupled in parallel between the input node 12 and the output node 14. This affects how the inductance of the first inductor L₁ and the second inductor L₂ are summed and in turn how the coupling between them affects the sum of their inductance. Accordingly, coupling the first inductor L₁ and the second inductor L₂ in this way may allow for better tuning of the resonant responses in the equivalent circuits discussed above.

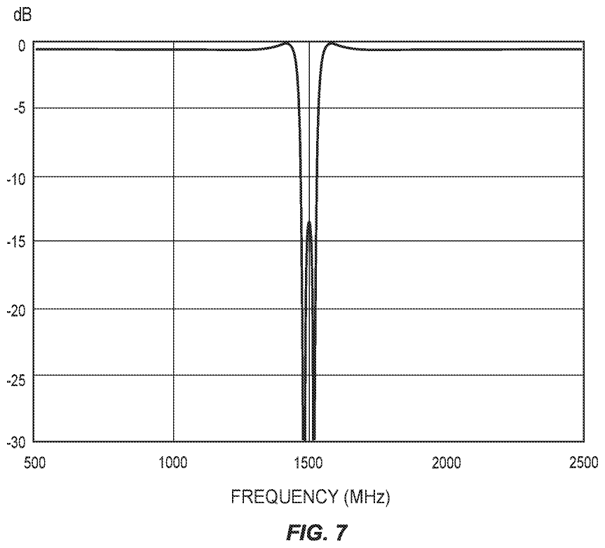

Decreasing the coupling factor k between the first inductor L₁ and the second inductor L₂ below zero may significantly improve the characteristics of the filter response of the RF filtering circuitry 10 in the configuration discussed above with respect to FIG. 5. This is illustrated by a graph in FIG. 7, which shows significantly less insertion loss outside of the notch response when the coupling factor k between the first inductor L₁ and the second inductor L₂ is decreased below zero.

Those skilled in the art will recognize improvements and modifications to the preferred embodiments of the present disclosure. All such improvements and modifications are considered within the scope of the concepts disclosed herein and the claims that follow.

What is claimed is:

1. Radio frequency (RF) filtering circuitry comprising:
an input node, an output node, and a shunt node;
a first bulk acoustic wave (BAW) resonator coupled between the input node and the output node;
a second BAW resonator coupled between an intermediate node and the shunt node;
a first inductor coupled between the input node and the intermediate node; and
a second inductor coupled between the output node and the intermediate node.

2. The RF filtering circuitry of claim 1 wherein the shunt node is coupled to ground.

3. The RF filtering circuitry of claim 2 wherein a series resonance frequency of the first BAW resonator is less than a series resonance frequency of the second BAW resonator.

4. The RF filtering circuitry of claim 3 wherein a coupling factor between the first inductor and the second inductor is greater than or equal to zero.

5. The RF filtering circuitry of claim 3 wherein a coupling factor between the first inductor and the second inductor is greater than zero.

6. The RF filtering circuitry of claim 2 wherein a series resonance frequency of the first BAW resonator is greater than a series resonance frequency of the second BAW resonator.

7. The RF filtering circuitry of claim 6 wherein a coupling factor between the first inductor and the second inductor is less than or equal to zero.

8. The RF filtering circuitry of claim 6 wherein a coupling factor between the first inductor and the second inductor is less than zero.

9. The RF filtering circuitry of claim 1 wherein a series resonance frequency of the first BAW resonator is less than a series resonance frequency of the second BAW resonator.

10. The RF filtering circuitry of claim 9 wherein a coupling factor between the first inductor and the second inductor is greater than or equal to zero.

11. The RF filtering circuitry of claim 9 wherein a coupling factor between the first inductor and the second inductor is greater than zero.

12. The RF filtering circuitry of claim 1 wherein a series resonance frequency of the first BAW resonator is greater than a series resonance frequency of the second BAW resonator.

13. The RF filtering circuitry of claim 12 wherein a coupling factor between the first inductor and the second inductor is less than or equal to zero.

14. The RF filtering circuitry of claim 12 wherein a coupling factor between the first inductor and the second inductor is less than zero.
